(19) United States
(12) Patent Application Publication
(10) Pub. No.: US 2016/0090457 A1
(43) Pub. Date: Mar. 31, 2016

(54) PREPREG, METAL-CLAD LAMINATE, AND PRINTED WIRING BOARD

(71) Applicant: Panasonic Intellectual Property Management Co., Ltd., Osaka (JP)

(72) Inventors: HIROAKI UMEHARA, Osaka (JP); HIROHARU INOUE, Osaka (JP)

(21) Appl. No.: 14/859,210

(22) Filed: Sep. 18, 2015

(30) Foreign Application Priority Data
Sep. 26, 2014 (JP) 2014-196599

(51) Int. Cl. C08J 5/24; H05K 1/03

(52) U.S. Cl. CPC C08J 5/24; H05K 1/0366; C08J 2363/00; C08J 2333/00; C08J 2433/00

(57) ABSTRACT

A prepreg satisfies the following properties (A) and (B).

(A) The resin flow of the prepreg measured under conditions of 170° C. and 30 kgf/cm² according to IEC 60249-3-1, 1981, is 0% or more and 5% or less.

(B) In a dynamic viscoelasticity test under conditions of a temperature of 30° C. or higher and 200° C. or lower, a temperature rising rate of 3° C./min, and a frequency of 0.5 Hz, a relation of 1≦Vb/Va≦15 is established, where Va is a minimum melt viscosity of the resin composition collected from the prepreg, and Vb is a melt viscosity of the collected resin composition at a temperature Tb, Tb=Ta+20° C., and Ta is a temperature when the melt viscosity is the minimum melt viscosity Va.

### BACKGROUND

1. Technical Field

The present disclosure relates to a prepreg, a metal-clad laminate formed from the prepreg, and a printed wiring board formed from the metal-clad laminate.

2. Description of the Related Art

Accompanying the reduced size and thickness of electronic devices, electronic components each having a surface mount package are being increasingly mounted on these electronic devices. Specific examples of such packages (PKG) include a package in which a semiconductor chip is mounted on a board, such as a chip-on-board (BOC) package.

In order to make electronic devices multifunctional, it is necessary to increase the number of electronic components to be mounted thereon. In order to satisfy this requirement, a type of package known as a Package on Package (PoP) is employed in which a plurality of sub-packages are laminated and mounted on a board followed by integrating into a single package. For example, these PoP are frequently employed in portable terminal devices such as smartphones or tablet computers.

The printed wiring board used for these packages is prepared by press-molding a prepreg which is a material for printed wiring boards.

Generally, when a prepreg is press-molded, a gap between conductors in a wiring board or the like is filled with a resin. Therefore, the resin of the prepreg has to be kept in an easily flowable state. However, when the resin of the prepreg easily flows, a metal-clad laminate obtained from the prepreg has a thick center portion and a thin external periphery. As the number of layers increases, such variation in in-plane thickness increases and causes variation in board processing accuracy, variation in quality, and a reduction in yield. When such variation is generated, performance may differ according to the places having different in-plane thicknesses. An adverse influence is exerted when an electronic component is mounted on the board.

Recently, requirements for the reliability and dimensional accuracy of a circuit have become stricter and an influence on signal speed accuracy or impedance caused by thickness accuracy may be increased.

On the other hand, when the resin of the prepreg does not easily flow, in-plane thickness accuracy is improved. However, the circuit filling properties of the resin are deteriorated and a space (void) between conductors easily remains. The circuit filling properties mean “ease when the resin covers a circuit (conductor pattern) that is formed on a plane surface of an insulating layer so as to project from the plane surface”. That is, the circuit filling properties are properties of resin covering a circuit without including air therein.

The following methods have been reported for the above problems. Japanese Patent Unexamined Publication No. 2003-298241 discloses a method of controlling the fluidity of a prepreg by using a mold while defining the fluidity. Japanese Patent Unexamined Publication No. 2011-14597 discloses a method of preventing a resin from flowing by using a laminating jig. Japanese Patent Unexamined Publication No. H06-152131 discloses a method of making in-plane thickness even while ensuring circuit filling properties by changing a curing degree of B stage at the outer side and the center portion of a prepreg, making the flow of the resin in the center portion easy, and making the flow of the resin of the outer side not easy.

### SUMMARY

According to an exemplary embodiment of the present disclosure, there is provided a prepreg having high thickness accuracy in an obtained metal-clad laminate and having excellent circuit formability, and the metal-clad laminate and a printed wiring board using the prepreg.

According to an aspect of the present disclosure, there is a prepreg that is formed by impregnating a fibrous substrate with a resin composition and heating and drying the resin composition, and satisfies following properties (A) and (B).

(A) The resin flow of the prepreg measured under conditions of 170° C. and 30 kgf/cm² according to IEC 60249-3-1, 1981 is 0% or more and 5% or less.

(B) In a dynamic viscoelasticity test under conditions of a temperature of 30° C. or higher and 200° C. or lower, a temperature rising rate of 3° C./min, and a frequency of 0.5 Hz, a relation of 1≦Vb/Va≦15 is established, where Va is a minimum melt viscosity of resin composition collected from the prepreg, Vb is a melt viscosity of the collected resin composition at a temperature Tb, Tb=Ta+20° C., and Ta is a temperature when the melt viscosity is minimum melt viscosity Va.

According to another aspect of the present disclosure, there is a metal-clad laminate including an insulting layer that is a cure product of the prepreg, and a metal foil formed on the insulting layer.

According to still another aspect of the present disclosure, there is a printed wiring board including an insulting layer that is a cure product of the prepreg, and a conductor pattern formed on the insulting layer.

According to the present disclosure, a metal-clad laminate and a printed wiring board prepared by using a prepreg have high thickness accuracy. Furthermore, the circuit formability of the printed wiring board is excellent.

### BRIEF DESCRIPTION OF DRAWINGS

FIG. 1 is a schematic sectional view of a prepreg according to an embodiment of the present disclosure.

FIG. 2 is a graph for explaining comparison of melt viscosity behavior of a prepreg according to an embodiment and melt viscosity behavior of a prepreg of the related art.

FIG. 3 is a schematic sectional view of a metal-clad laminate according to an embodiment of the present disclosure.

FIG. 4 is a schematic sectional view of a printed wiring board according to an embodiment of the present disclosure.

### DETAILED DESCRIPTION OF PREFERRED EMBODIMENTS

Prior to description of embodiments of the present disclosure, problems in the related art will be simply described.

First, in the technique disclosed in Japanese Patent Unexamined Publication No. 2003-298241, a complicated molding jig is required. Between hot platens, in addition to a plate, a copper foil at the time of molding, and a prepreg, a complicated oscillating plate, and a heating member that inhibits resin flow to a horizontal direction are required to be provided. Accordingly, the operation is complicated, leading to an increase in cost. In the technique disclosed in Japanese Patent Unexamined Publication No. 2011-14597, a complicated jig is also required.

In the technique disclosed in Japanese Patent Unexamined Publication No. H06-152131, a process such as a pre-heat treatment is required to produce a prepreg. Moreover, it is very difficult to prepare a prepreg that is evenly cured in this method.

As in the techniques disclosed in the above Japanese Patent Unexamined Publications, both thickness accuracy and circuit filling properties cannot be achieved only by control of the resin flow.

Hereinafter, embodiments of the present disclosure will be described. However, the present disclosure is not limited to these embodiments.

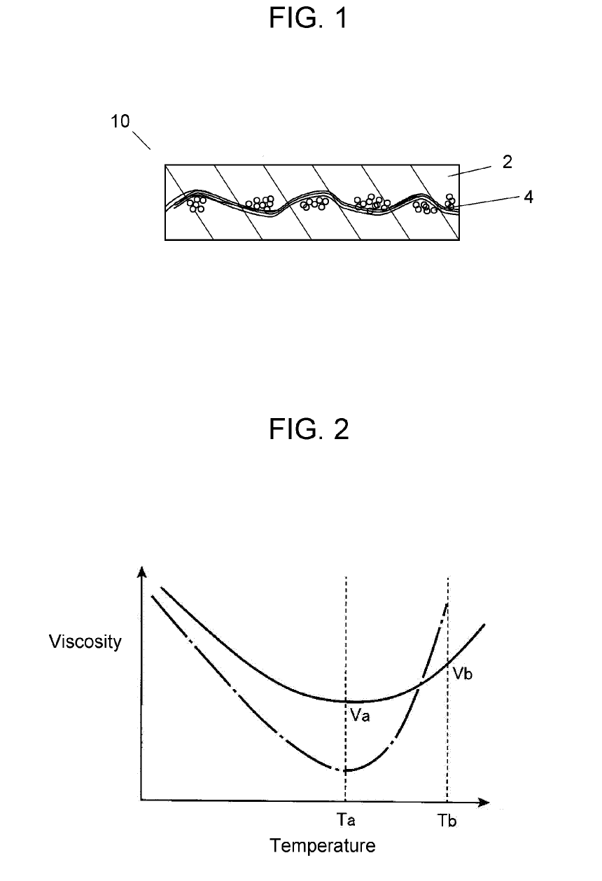

FIG. 1 is a schematic sectional view of prepreg 10 according to an embodiment of the present disclosure. Prepreg 10 has fibrous substrate 4 and resin composition 2 with which substrate 4 is impregnated. That is, prepreg 10 is prepared by impregnating substrate 4 with resin composition 2.

Specifically, prepreg 10 is formed by impregnating substrate 4 with resin composition 2 and then heating and drying resin composition 2 until resin composition 2 is semi-cured (so-called B stage state). Prepreg 10 satisfies following properties (A) and (B).

(A) The resin flow of prepreg 10 measured under conditions of 170° C. and 30 kgf/cm² according to JIS C6521 (corresponding to IEC 60249-3-1, 1981) is 0% or more and 5% or less.

(B) In a dynamic viscoelasticity test under the conditions of a temperature of 30° C. or higher and 200° C. or lower, a temperature rising rate of 3° C./min, and a frequency of 0.5 Hz, when the minimum melt viscosity of resin composition 2 collected from prepreg 10 is Va and a temperature when the melt viscosity is minimum melt viscosity Va is Ta, melt viscosity Vb of collected resin composition at temperature Tb of Ta+20° C. is 1 time or more and 15 times or less of minimum melt viscosity Va.

First, when the resin flow of prepreg 10 satisfies property (A), the in-plane thickness accuracy becomes satisfactory. When the resin flow measured under the above-described conditions is more than 5%, resin composition 2 is flowable and the amount of the resin protruding is increased. Therefore, variation in thickness in the surface of the substrate prepared by using prepreg 10, particularly, at the center portion and the outer periphery of the substrate, may become large. On the other hand, as in the embodiment, when the resin flow is reduced, the protrusion of the resin is inhibited and variation in in-plane thickness can be reduced. However, only with such conditions, satisfactory circuit filling properties may not be obtained.

And so, it is important to satisfy the melt viscosity behavior defined by property (B). The melt viscosity behavior defied in the embodiment refers to the melt viscosity behavior of resin composition 2 collected from prepreg 10.

A method of collecting resin composition 2 from prepreg 10 is not particularly limited and for example, resin composition 2 can be collected from prepreg 10 according to a part of a method of measuring a gel time of resin composition defined in JIS C6521. That is, resin composition 2 is separated from prepreg 10 by rubbing it and substrate 4 is removed from prepreg 10 so that a semi-cured product of resin composition 2 can be collected. The collected semi-cured product is compressed to prepare a resin tablet. The resin tablet has, for example, a diameter of 10 mm and a height of 3 mm. The melt viscosity of resin composition 2 can be measured by performing a dynamic viscoelasticity test using this tablet.

FIG. 2 is a graph for schematically showing the melt viscosity behavior of a resin composition collected from a general prepreg of the related art and the melt viscosity behavior of resin composition 2 collected from prepreg 10 according to the embodiment. The solid line indicates the melt viscosity behavior of resin composition 2 of the embodiment and the dashed line indicates the melt viscosity behavior of the resin composition of the prepreg of the related art. Temperature Ta represents a temperature at the time when the viscosity reaches minimum melt viscosity Va, temperature Tb represents a temperature which is Ta+20° C., and melt viscosity Vb represents a melt viscosity at temperature Tb. The vertical axis in FIG. 2 is expressed in a logarithmic scale.

As indicated by the dashed line, in the related art, circuit filling properties are improved by setting the minimum melt viscosity Va to be low. In contrast, in the embodiment, as indicated by the solid line, compared to the prepreg in the related art, a temperature range near the minimum melt viscosity Va is relatively widened while maintaining a slightly high minimum melt viscosity Va. Thus, satisfactory circuit filling properties are achieved while the fluidity of the resin is ensured so that the resin from flowing out to the horizontal direction (in-plane direction of substrate 4) is prevented.

That is, as the properties of resin composition 2, first, resin composition 2 does not flow out in the in-plane direction of substrate 4 due to slow curing. On the other hand, since the time for curing of the resin is long and the fluidity can be ensured for a long period of time, the circuit filling properties of the resin is also satisfactory.

When Vb/Va is more than 15, the speed of curing is increased, and when the resin flow satisfies property (A) and the amount of resin flow is small, the circuit filling properties may be deteriorated. When Vb/Va is smaller than 1, insufficient curing may occur.

The range of minimum melt viscosity Va of resin composition 2 collected from prepreg 10 is preferably about 1×10⁴ poises to 1×10⁷ poises. As long as the melt viscosity is within this range, the surface of metal-clad laminate 20 can be made smooth while ensuring appropriate fluidity.

As described above, metal-clad laminate 20 prepared from prepreg 10 using resin composition 2 satisfying properties (A) and (B) has excellent in-plane thickness accuracy and circuit filling properties.

The gel time of resin composition 2 collected from prepreg 10 measured according to JIS C6521 is preferably 90 seconds or longer and 360 seconds or shorter at 200° C.

It can be considered that by setting this gel time to be relatively long, in hot press molding performed by pressing prepreg 10, the time until the resin is cured become long and circuit filling properties are further improved. In other words, when the gel time under the above conditions is 90 seconds or longer and 360 seconds or shorter, circuit filling properties are more reliably achieved.

When the gel time is shorter than 90 seconds, circuit filling properties may be deteriorated. On the other hand, when the gel time is longer than 360 seconds, insufficient curing may occur.

In prepreg 10, resin composition 2 with which substrate 4 is impregnated preferably contains the following components.

(1) Polymer having a glass transition temperature (Tg) of 100° C. or lower and a weight average molecular weight of 10,000 or more and 1,000,000 or less

(2) Epoxy resin curing agent having a phenolic hydroxyl group equivalent of 400 g/eq or more and 1,000 g/eq or less

(3) Epoxy resin having two or more epoxy groups in one molecule

(4) Inorganic filler

Such resin composition 2 is used to more reliably exhibit the above described effects. Hereinafter, each component will be described in detail.

### Component (1): Polymer

A polymer of Component (1) is an effective component to inhibit resin flow (protrusion of the resin). When the gel time of resin composition 2 is long, generally, resin flow is increased. When the resin composition contains a polymer, resin flow is inhibited.

Component (1) is not particularly limited as long as the component has a Tg of 100° C. or lower and a weight average molecular weight of 10,000 or more and 1,000,000 or less. For example, acrylic rubber is preferably used.

When the Tg of the polymer is 100° C. or lower, at the time of hot press molding, the fluidity of the molecules of the polymer is increased and the viscosity before melted is lowered. Thus, the width of the melt viscosity of resin composition 2 tends to be widened. Therefore, molding is easily performed. Tg is not particularly limited as for the lower side. Tg is a value obtained by subjecting the polymer to differential scanning calorimetry (DSC).

When the weight average molecular weight of the polymer is less than 10,000, the fluidity of the resin is increased and the resin flow is not easily inhibited. There is a possibility of in-plane thickness variation increasing. On the other hand, when the weight average molecular weight is more than 1,000,000, substrate 4 may not be easily impregnated with a vanish at the time of preparing prepreg 10 due to an increase in viscosity of varnish.

Preferable examples thereof include a polymer having repeating units expressed by the following structural formulae (I) and (II) and having an epoxy group.

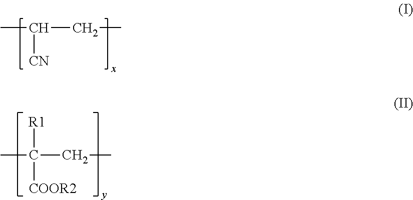

In the formulae (I) and (II), 0≦x/(x+y)≦0.35 is satisfied, R1 represents H or CH₃, and R2 represents H or an alkyl group. That is, the polymer preferably has a main chain having structures expressed by the formulae (I) and (II), and has an epoxy group bonded with the main chain. The heat resistance of the cured product of resin composition 2 is improved by using such a polymer.

Since 0≦x/(x+y)≦0.35 is satisfied, there is a case of x being 0 where the main chain of Component (1) is composed of only the structure expressed by the formula (II). Except for this case, the sequence of the structures expressed by the formulae (I) and (II) is not particularly limited.

It is not preferable that Component (1) has an unsaturated bond such as a double bond and a triple bond between carbon atoms. That is, carbon atoms of Component (1) are preferably bonded by a saturated bond (single bond). When a prepreg containing a component having an unsaturated bond between carbon atoms, the prepreg comes to lose elasticity and becomes easily brittle when oxidized with the passage of time.

### Component (2): Epoxy Resin Curing Agent

An epoxy resin curing agent used for resin composition 2 is not particularly limited as long as the curing agent has a phenolic hydroxyl group equivalent of 400 g/eq or more and 1,000 g/eq or less. For example, a polyphenylene ether (PPE) copolymer is preferably used. When such a curing agent having a large hydroxyl group equivalent is used, a mild curing reaction occurs.

Specifically, for example, PPE having a number average molecular weight (Mn) of 500 to 2,000 is preferably used and Mn is preferably 650 to 1,500. When the Mn is 500 or more, a cured product having sufficient heat resistance can be obtained. When the Mn is 2,000 or less, reactivity with an epoxy group in an epoxy resin as Component (3), which will be described later, is sufficient. Therefore, the heat resistance of the cured product is further improved and the dielectric constant and dielectric dissipation factor of the cured product can be kept to be low.

The number average molecular weight of Component (2) can be measured by using, for example, gel permeation chromatography.

Component (2) is preferably PPE having phenolic hydroxyl groups with an average number of 1.5 to 3 at the molecule terminal in one molecule. Component (2) is more preferably PPE having phenolic hydroxyl groups with an average number of 1.8 to 2.4 at the molecule terminal in one molecule. When the average number of terminal hydroxyl groups is 1.5 to 3, reactivity with an epoxy group in an epoxy resin as Component (3), which will be described later, is sufficient. Therefore, the heat resistance of the cured product is further improved and the dielectric constant and dielectric dissipation factor of the cured product can be kept to be low.

The number of hydroxyl groups in Component (2) is recognized from the value of standard of a PPE product to be used. Specifically, for example, the number of hydroxyl groups at the molecule terminal is a numerical value expressed as an average value of hydroxyl groups per molecule of all PPE present in 1 mole of Component (2).

Furthermore, the intrinsic viscosity of Component (2) measured in methylene chloride at 25° C. is preferably 0.03 dl/g or more and 0.12 dl/g or less, and more preferably 0.06 dl/g or more and 0.095 dl/g or less. When the intrinsic viscosity is within such a range, it is considered that the heat resistance of the cured product is improved and the component can sufficiently react with Component (3).

The intrinsic viscosity of Component (2) is also recognized from the value of standard of a PPE product to be used. Specifically, the intrinsic viscosity is obtained by, for example, measuring a solution containing 0.18 g of Component (2) dissolved in 45 ml of a methylene chloride (solution temperature: 25° C.) with a viscometer. As the viscometer, a capillary viscometer is used. For example, an AVS 500 Visco System, manufactured by Schott Instruments GmbH, may be used.

Specific examples of PPE of Component (2) include a polyphenylene ether copolymer composed of 2,6-dimethylphenol and at least one of a bifunctional phenol and a trifunctional phenol, and a copolymer having polyphenylene ether such as poly(2,6-dimethyl-1,4-phenylene oxide) as a main component. Examples of the bifunctional phenol include tetramethyl bisphenol A.

More specific examples of PPE which is Component (2) include a PPE having a structure expressed in the following formula (1).

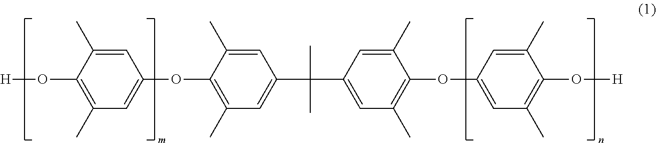

In the formula (1), “m” and “n” may be a polymerization degree as long as the melt viscosity is within the above-mentioned range. Specifically, a total value of “m” and “n” is preferably 1 to 30. “m” is preferably 0 to 20 and “n” is preferably 0 to 20. When PPE having such a structure is used, a resin composition having further excellent dielectric properties and heat resistance of a cured product can be reliably obtained.

PPE can be produced by a method described in WO 2007/067669A. Commercially available PPE products can be used. For example, “SA-90” manufactured by SABIC's Innovative Plastics can be used.

### Component (3): Epoxy Resin

In resin composition 2, an epoxy resin as Component (3) is a component for curing with the curing agent of Component (2) and is blended for adjusting the heat resistance and/or Tg.

The epoxy resin used as Component (3) is not particularly limited as long as the epoxy resin has two or more epoxy groups in one molecule.

The number of epoxy groups is recognized from the value of standard of an epoxy resin product to be used. Specifically, for example, the number of epoxy groups of the epoxy resin is expressed as a numerical value showing an average value of epoxy groups per molecule of all epoxy resin present in 1 mole of epoxy resin.

Specific examples thereof include bisphenol A-type epoxy resins, bisphenol F-type epoxy resins, biphenyl type epoxy resins, cresol novolac type epoxy resins, dicyclopentadiene type epoxy resins, naphthalene-ring-containing epoxy resins, alicyclic epoxy resins, bromine-containing epoxy resins, and hydrogenated epoxy resins thereof. These may be used alone or in combination of two or more thereof.

Preferably, at least one selected from the group consisting of naphthalene-ring-containing epoxy resins, dicyclopentadiene type epoxy resins, and cresol novolac type epoxy resins is used. When such an epoxy resin is used, it is possible to more reliably obtain a high Tg and high heat resistance.

Regarding the respective blending amount, when a total of Component (2) and Component (3) is 100 parts by mass, the ratio of Component (1) is preferably 5 parts by mass to 40 parts by mass. Within this range, in-plane thickness accuracy and circuit filling properties can be improved without deteriorating the heat resistance of the laminate prepared using prepreg 10.

From the viewpoint of heat resistance, the ratio of the epoxy equivalent of Component (3) with respect to the hydroxyl group equivalent of Component (2) is preferably 1.0 or more and 4.0 or less. That is, it is preferable that the mass ratio between Component (2) and Component (3) satisfies this condition.

### Component (4): Inorganic Filler

When resin composition 2 contains an inorganic filler, resin composition 2 does not easily flow and in-plane thickness accuracy is satisfactory.

The inorganic filler that can be used in the embodiment is not particularly limited. Examples of the inorganic filler include spherical silica, barium sulfate, silicon oxide powder, crushed silica, burnt talc, barium titanate, titanium oxide, clay, alumina, mica, boehmite, zinc borate, zinc stannate, other metal oxides and metal hydrates. When resin composition 2 contains such an inorganic filler, it is possible to improve a dimensional stability of metal-clad laminate 20 prepared using prepreg 10.

When silica is used as the inorganic filler, the dielectric dissipation factor (Df) of metal-clad laminate 20 can be preferably lowered.

When resin composition 2 contains Component (4), the ratio of Component (4) with respect to a total 100 parts by mass of Components (1), (2), and (3) is preferably 300 parts by mass or less. When the content of the inorganic filler is more than 300 parts by mass, at the time of preparing prepreg 10, substrate 4 is not easily impregnated with the vanish of resin composition 2. The adhesion strength to the copper foil may be deteriorated.

### Other Components

Resin composition 2 may contain components other than the above components. For example, the resin composition may contain a curing accelerator (catalyst).

Since there is a case in which the gel time of resin composition 2 can be adjusted according to the type and the blending amount of the curing accelerator, the curing accelerator can be appropriately selected and used.

Such a curing accelerator is not particularly limited. For example, imidazoles and derivatives thereof, organophosphorus compounds, metal soaps such as zinc octoate, secondary amines, tertiary amines, and quaternary ammonium salts can be used.

Resin composition 2 may further contain a light stabilizer, a viscosity adjusting agent, a flame retardant other than the above components.

### Preparation of Prepreg

For example, when prepreg 10 is prepared using resin composition 2 containing above-described Components (1) to (4), by blending Components (1) to (4), and the curing accelerator as required, resin composition 2 can be prepared. The vanish of resin composition 2 can be prepared by diluting resin composition 2 with a solvent.

Specifically, for example, first, each component ((1) to (3) and the like) which can be dissolved in an organic solvent among the components constituting resin composition 2 is put into the organic solvent and is dissolved to prepare a solution. At this time, as required, the organic solvent may be heated. Thereafter, the inorganic filler (Component (4)) or the like used as required and incorruptible in the organic solvent is added to this solution. The component is dispersed to a predetermined dispersion state with a ball mill, a bead mill, a planetary mixer, a roll mill, or the like. In this manner, a varnish-like resin composition is prepared. The above-described organic solvent is not particularly limited. Specifically, ketone-based solvents such as acetone, methyl ethyl ketone and cyclohexanone, aromatic solvents such as toluene and xylene, nitrogen containing solvents such as dimethylformamid, and the like can be used.

Prepreg 10 can be produced by impregnating substrate 4 with the thus-prepared resin vanish and drying the resin vanish. A molded body such as a printed wiring board having high thickness accuracy or the like can be produced using such prepreg 10.

Specific examples of substrate 4 used when prepreg 10 is produced include glass cloth, aramid cloth, polyester cloth, glass nonwoven cloth, aramid nonwoven cloth, polyester nonwoven cloth, pulp paper, Linter paper or the like. When glass cloth is used, a metal-clad laminate with excellent mechanical strength can be obtained and the glass cloth that has been flattened is particularly preferable. Flattening can be performed by pressing the glass cloth continuously with a pressing roll at an appropriate pressure to compress the yarn in a flat shape. Generally, substrate 4 having a thickness of, for example, 10 μm to 200 μm can be used.

Substrate 4 is impregnated with resin composition 2 by dipping in or applying resin composition 2. As required, the impregnation operation can be repeated several times. In this case, impregnation can be repeated using multiple resin compositions with different compositions and/or concentrations to finally adjust the composition and the amount of impregnation as desired.

After substrate 4 is impregnated with resin composition 2, substrate 4 is heated under the desired heating conditions, such as a temperature of 110° C. to 190° C. and a time of 3 minutes to 15 minutes to prepare a semi-cured (B stage) prepreg 10.

### Metal-Clad Laminate and Printed Wiring Board

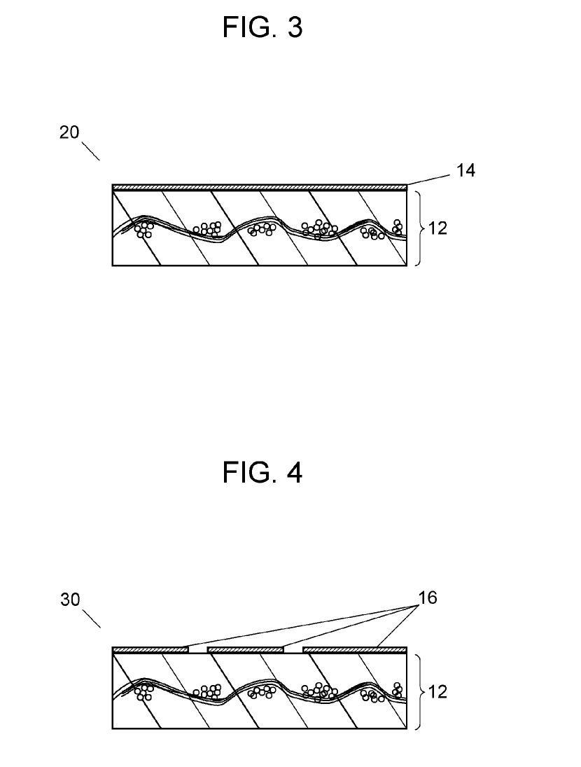

Metal-clad laminate 20 shown in FIG. 3 can be prepared using prepreg 10 thus prepared. FIG. 3 is a schematic sectional view of metal-clad laminate 20. Metal-clad laminate 20 has insulating layer 12 which is a cured product of prepreg 10 and metal foil 14 laminated on insulating layer 12.

Examples of a method of preparing metal-clad laminate 20 include the following method. One sheet or a stack of plural sheets of prepreg 10 is covered on either the top or bottom or both with metal foil 14 such as a copper foil, and the layers are then laminated together by hot press molding to prepare a laminate plated on one or both sides with the metal foil. That is, metal-clad laminate 20 is prepared by laminating metal foil 14 on prepreg 10 and subjecting the layers to hot press molding.

The hot press conditions can be set appropriately according to the thickness of metal-clad laminate 20 to be produced, the type of resin composition 2 of prepreg 10 and the like. For example, a temperature of 170° C. to 210° C., a pressure of 1.5 MPa to 4.0 MPa and a time of 60 minutes to 150 minutes can be used, for example.

FIG. 4 is a schematic sectional view of printed wiring board 30. Printed wiring board 30 has insulating layer 12 and conductor pattern 16 formed on insulating layer 12. That is, it is possible to prepare printed wiring board 30 in which conductor pattern 16 obtained by etching metal foil 14 on the surface of metal-clad laminate 20 to form a circuit, is provided on the surface as the circuit as shown in FIG. 4. As described, printed wiring board 30 is prepared by partially removing metal foil 14 on the surface of metal-clad laminate 20 to form a circuit.

Printed wiring board 30 has both excellent in-plane thickness accuracy and excellent circuit filling properties without variation in quality when printed wiring board 30 is prepared using metal-clad laminate 20. When a package to which a semiconductor chip is bonded is formed using printed wiring board 30, mounting is easy and there is no variation in quality. An excellent signal speed and impedance can be obtained. Since prepreg 10 has excellent circuit filling properties, even in the case in which complicated conductor pattern 16 is formed, printed wiring board 30 can be easily prepared without voids.

Hereinafter, the above-described effects will be described in detail using more specific examples. However, the present disclosure is not limited to these examples.

First, each component used in respective samples when the resin composition is prepared will be described.

### Component (1): Polymer

Polymer 1: Epoxy-modified acrylic resin, “SG-P3 improve 225”, manufactured by Nagase ChemteX Corporation, having repeating units expressed by the structural formulae (I) and (II) in which in the formula (II), R1 represents a hydrogen atom or a methyl group and R2 represents a methyl group or an ethyl group, and a Mw of 650,000 and a Tg of 10° C.
Polymer 2: Epoxy-modified acrylic resin, “SG-P3-Mw1”, manufactured by Nagase ChemteX Corporation, having repeating unit expressed by the structural formulae (I) and (II) in which in the formula (II), R1 represents a hydrogen atom and R2 represents a butyl group or an ethyl group, and a Mw of 260,000 and a Tg of 12° C.
Polymer 3: Polystyrene, “ST-120”, manufactured by Sanyo Chemical Industries, Ltd., having a Mw of 10,000 and a Tg of 42° C.
Polymer 4: Polystyrene, “ST-95”, manufactured by Sanyo Chemical Industries, Ltd., having a Mw of 4,000 and a Tg of 42° C.

### Component (2): Curing Agent

Epoxy resin curing agent 1: “SA-90” manufactured by SABIC's Innovative Plastics, having a number average molecular weight of 1,500, an average number of terminal hydroxyl groups of 1.9, and a hydroxyl group equivalent of 790 g/eq
Epoxy resin curing agent 2: Phosphorus-containing phenolic resin, “XZ92741”, manufactured by Dow Chemical Company, having a hydroxyl group equivalent of 550 g/eq
Epoxy resin curing agent 3: Phenol novolac resin, “TD2090”, manufactured by DIC Corporation, having a hydroxyl group equivalent of 105 g/eq

### Component (3): Epoxy Resin

Epoxy resin 1: Naphthalene type epoxy resin, “HP6000”, manufactured by DIC Corporation, having an epoxy equivalent of 250 g/eq

### Component (4): Inorganic Filler

Spherical silica 1: Spherical silica surface-treated with epoxy silane, “SC2500-SEJ” manufactured by Admatechs

### Cure Accelerator

2E4MZ: 2-ethyl-4-methyl imidazole manufactured by Shikoku Chemicals Corporation
Zinc octanoate: “Zn-OCTOATE” manufactured by DIC Corporation

### Preparation of Prepreg

First, the epoxy resin curing agent as Component (2) and toluene are mixed and the liquid mixture is heated to 80° C. Through this operation, Component (2) is dissolved in toluene to prepare a 50% by mass toluene solution of Component (2). Thereafter, the epoxy resin as Component (3) and the polymer as Component (1) are added to the toluene solution in the blending ratio shown in Tables 1 to 3 and then the mixture is stirred for 30 minutes to dissolve the components completely. The curing accelerator and the inorganic filler as Component (4) are further added thereto and dispersed with a ball mill. In this manner, a varnish-like resin composition (resin varnish) is prepared.

Prepregs are prepared in the following manner by using the resin varnish thus prepared.

In each of the prepregs, a #2116 type glass cloth or WEA116E glass cloth, manufactured by Nitto Boseki Co., Ltd., is used as a fibrous substrate. The substrate is impregnated with the resin varnish so as to have a thickness of 125 m after curing, and then the impregnated body is heated and dried at 130° C. for 3 minutes until the resin varnish is semi-cured. In this manner, a prepreg is prepared.

### Metal-Clad Laminate

Six sheets of the prepregs described above are stacked and copper foils (GT-MP, manufactured by Furukawa Electric Co., Ltd.) with a thickness of 35 μm are disposed on the respective surfaces of the stack to obtain a body to be pressed. Under the conditions of a temperature of 220° C. and a pressure of 40 kgf/cm² in a vacuum, the body to be pressed is heated and pressed for 120 minutes. In this manner, a copper-clad laminate with a thickness of 0.75 mm in which copper foils are bonded to the respective surfaces is prepared.

The prepreg and copper-clad laminate of each sample prepared in the above-described manner are used as evaluation samples and each evaluation test is performed in the methods shown below.

### Evaluation

### Resin Flow

The resin fluidity of each prepreg is measured according to JIS C6521 (IEC 60249-3-1, 1981). The prepreg is hot-pressed for 15 minutes under the molding conditions of a temperature of 170° C. and a pressure of 30 kgf/cm². Six sheets of prepregs are used for measurement as described above.

### Gel Time

The gel time of the resin composition collected from the prepreg is measured according to JIS C6521 (IEC 60249-3-1, 1981). First, the resin composition is separated from the prepreg by rubbing the prepreg such that glass fibers are not incorporated and the resin composition in the B-stage state is collected from the prepreg. This resin composition is placed on a hot platen with a temperature set to 200° C. and the gel time is measured.

### Va and Vb

The melt viscosity of the resin composition collected from the prepreg is measured by a dynamic viscoelasticity test. First, as in the case of measuring the gel time of the resin composition, the resin composition is collected from the prepreg. The resin composition is compressed to prepare a tablet having a diameter of 10 mm and a height of 3 mm. The melt viscosity of the resin composition is measured by using a dynamic viscoelasticity measuring apparatus (Rheosol-G3000, manufactured by UBM Japan Co., Ltd.) under the following conditions while using the tablet as a measurement object and a parallel plate having a diameter of 18 mm.
Measurement temperature: 30° C. to 200° C.
Temperature rising rate: 3° C./min
Frequency: 0.5 Hz

In the obtained melt viscosity chart, the minimum viscosity value (η*) is set to Va, the temperature when the viscosity value has the minimum value is set to Ta, and the viscosity value at the time of Tb (=Ta+20° C.) is set to Vb. The obtained Va and Vb are used to calculate Vb/Va.

### In-Plane Thickness

The prepreg is prepared to have a size of 340 mm×510 mm and a copper-clad laminate is prepared as described above. The copper foil is removed from the copper-clad laminate by etching and a cured product that is an insulating layer is prepared. The cured product is diagonally cut and the thickness at plural positions 5 mm inside from the cut surface is measured with a micrometer (MDC-25SX, manufactured by Mitutoyo Corporation). At this time, first, the thickness of the center portion of the cured product is measured and then the thickness of 14 portions provided on the right and left sides, respectively, with an interval of 20 mm from the center portion along the cut surface, that is, the thickness values at total 29 portions are measured. A difference between the maximum thickness value and the minimum thickness value in the thickness values of 29 portions is evaluated as an in-plane thickness difference. When the in-plane thickness difference is small, it is evaluated that the in-plane thickness accuracy is high. The center portion of the cured product can be visually confirmed. The end portion of the glass cloth is the end portion of the cured product and the center portion of the cured product is the middle of the glass cloth.

### Circuit Filling Properties

A lattice-like conductor pattern is formed in the copper foils on the respective surfaces of the copper-clad laminate such that the residual copper rate is 50%, respectively. Thus, a schematic circuit board is formed. On each surface of the circuit board, the prepreg is laminated and under the same conditions as those when the copper-clad laminate is produced, this body to be pressed is pressed while being heated. Regarding the thus-formed laminated body (laminated body for evaluation), when a gap between the conductor patterns is sufficiently filled with the resin and the like derived from the prepreg and no voids are formed, the laminated body is evaluated as “OK”. That is, when voids are not confirmed between portions of the conductor pattern, the laminated body is evaluated as “OK”. When the gap between portions of the conductor pattern is not sufficiently filled with the resin and the like derived from the prepreg and void formation is confirmed, the laminated body is evaluated as “NG”. The voids can be visually confirmed.

### Dielectric Properties (Dielectric Constant (Dk) and Dielectric Dissipation Factor (Df))

The cured product obtained by removing the copper foil from the copper-clad laminate is used as an evaluation object and the dielectric constant and the dielectric dissipation factor at 10 GHz are measured by a cavity resonator perturbation method. Specifically, using a network analyzer (N5230A, manufactured by Agilent Technologies), the dielectric constant and the dielectric dissipation factor of the evaluation object at 10 GHz are measured.

### Copper Foil Adhesion Strength

In the copper-clad laminate mentioned above, the peel strength of the copper foil from the insulating layer is measured according to JIS C 6481 (corresponding to IEC 60249-1, 1982). A pattern having a width of 10 mm and a length of 100 mm is formed on the copper foil and the pattern is peeled off by using a tensile tester at a speed of 50 mm/min. At this time, the peel strength is measured. The peel strength measured in this manner is set as copper foil adhesions strength. The measuring unit is kN/m.

The above-obtained results are summarized in Tables 1 to 3. In Tables, the numerical values of each component represent parts by mass.

TABLE 1

| | | E1 | E2 | E3 | E4 | E5 | E6 | C2 |
|---|---|---|---|---|---|---|---|---|
| (1) | Polymer 1 | 25 | | | | 40 | 25 | 25 |
| | Polymer 2 | | 25 | | | | | |
| | Polymer 3 | | | 25 | | | | |
| | Polymer 4 | | | | 25 | | | |
| (2) | Epoxy resin curing agent 1 | 75 | 75 | 75 | 75 | 75 | | |
| | Epoxy resin curing agent 2 | | | | | | 67 | |
| | Epoxy resin curing agent 3 | | | | | | | 27 |
| (3) | Epoxy resin 1 | 25 | 25 | 25 | 25 | 25 | 33 | 73 |
| Curing | Imidazole | 0.25 | 0.25 | 0.25 | 0.25 | 0.25 | 0.25 | 0.25 |
| accelerator | Zinc octanoate | 1 | 1 | 1 | 1 | 1 | 1 | 1 |
| (4) | Spherical silica 1 | 125 | 125 | 125 | 125 | 140 | 125 | 125 |
| Total | | 251.25 | 251.25 | 251.25 | 251.25 | 281.25 | 251.25 | 251.25 |
| Epoxy equivalent/Hydroxyl equivalent | | 1.1 | 1.1 | 1.1 | 1.1 | 1.1 | 1.1 | 1.1 |
| Evaluation | Resin flow (%) | 1.0 | 2.0 | 3.0 | 5.0 | 0.5 | 2.0 | 2.0 |
| | Va (poise) | 4.0E+05 | 3.1E+05 | 2.0E+05 | 1.3E+05 | 4.5E+05 | 3.5E+05 | 1.2E+05 |
| | Vb (poise) | 2.1E+06 | 2.0E+06 | 1.8E+06 | 1.8E+06 | 2.2E+06 | 3.0E+06 | 3.5E+06 |
| | Vb/Va | 5.3 | 6.5 | 9.0 | 13.8 | 4.9 | 8.6 | 29.2 |
| | Gel time (sec) | 210 | 200 | 200 | 200 | 185 | 170 | 70 |
| | In-plane thickness | 6 | 7 | 10 | 13 | 5 | 10 | 8 |
| | difference (μm) | | | | | | | |
| | Circuit filling properties | OK | OK | OK | OK | OK | OK | NG |
| | Dk | 4.0 | 4.0 | 3.9 | 3.9 | 4.1 | 4.5 | 4.6 |
| | Df | 0.010 | 0.010 | 0.009 | 0.009 | 0.011 | 0.019 | 0.020 |
| | Copper foil adhesion | 0.60 | 0.60 | 0.58 | 0.58 | 0.50 | 0.55 | 0.55 |
| | strength (kN/m) | | | | | | | |

TABLE 2

| | | E1 | E7 | E8 | E9 | Cl | C5 |
|---|---|---|---|---|---|---|---|
| (1) | Polymer 1 | 25 | 25 | 25 | 25 | | |
| | Polymer 2 | | | | | | |
| | Polymer 3 | | | | | | |
| | Polymer 4 | | | | | | |
| (2) | Epoxy resin curing agent 1 | 75 | 75 | 75 | 75 | 75 | |
| | Epoxy resin curing agent 2 | | | | | | |
| | Epoxy resin curing agent 3 | | | | | | 27 |
| (3) | Epoxy resin 1 | 25 | 25 | 25 | 25 | 25 | 73 |
| Curing | Imidazole | 0.25 | 0.25 | 0.25 | 0.25 | 0.25 | 0.25 |
| accelerator | Zinc octanoate | 1 | 1 | 1 | 1 | 1 | 1 |
| (4) | Spherical silica 1 | 125 | 250 | 312.5 | 375 | 100 | 100 |
| Total | | 251.25 | 376.25 | 438.75 | 501.25 | 201.25 | 201.25 |
| Epoxy equivalent/Hydroxyl equivalent | | 1.1 | 1.1 | 1.1 | 1.1 | 1.1 | 1.1 |
| Evaluation | Resin flow (%) | 1.0 | 0.5 | 0.1 | 0.0 | 10.0 | 20.0 |
| | Va(poise) | 4.0E+05 | 6.5E+05 | 1.2E+06 | 1.6E+06 | 1.2E+05 | 8.0E+04 |
| | Vb(poise) | 2.1E+06 | 3.0E+06 | 5.2E+06 | 5.9E+06 | 1.7E+06 | 3.5E+06 |
| | Vb/Va | 5.3 | 4.6 | 4.3 | 3.7 | 14.2 | 43.8 |
| | Gel time (sec) | 210 | 195 | 185 | 180 | 185 | 130 |
| | In-plane thickness | 6 | 5 | 4 | 3 | 23 | 35 |
| | difference (μm) | | | | | | |
| | Circuit filling properties | OK | OK | OK | OK | OK | OK |
| | Dk | 4.0 | 4.1 | 4.2 | 4.3 | 3.9 | 4.6 |
| | Df | 0.010 | 0.0085 | 0.008 | 0.0075 | 0.009 | 0.020 |
| | Copper foil adhesion | 0.60 | 0.50 | 0.42 | 0.30 | 0.70 | 0.55 |
| | strength (kN/m) | | | | | | |

TABLE 3

| | | E1 | E10 | C3 | C4 |
|---|---|---|---|---|---|
| (1) | Polymer 1 | 25 | 25 | 25 | 25 |
| | Polymer 2 | | | | |
| | Polymer 3 | | | | |
| | Polymer 4 | | | | |
| (2) | Epoxy resin curing agent 1 | 75 | 75 | | |
| | Epoxy resin curing agent 2 | | | | |
| | Epoxy resin curing agent 3 | | | 27 | 27 |
| (3) | Epoxy resin 1 | 25 | 25 | 73 | 73 |
| Curing | Imidazole | 0.25 | 0.3 | 0.2 | 0.1 |
| accelerator | Zinc octanoate | 1 | 1 | 0 | 0 |
| (4) | Spherical silica 1 | 125 | 125 | 125 | 125 |
| Total | | 251.25 | 251.3 | 250.2 | 250.1 |
| Epoxy equivalent/Hydroxyl equivalent | | 1.1 | 1.1 | 1.1 | 1.1 |
| Evaluation | Resin flow (%) | 1.0 | 0.5 | 5.0 | 7.0 |
| | Va (poise) | 4.0E+05 | 4.2E+05 | 1.1E+05 | 1.1E+05 |
| | Vb (poise) | 2.1E+06 | 2.9E+06 | 3.0E+06 | 2.8E+06 |
| | Vb/Va | 5.3 | 6.9 | 27.3 | 25.5 |
| | Gel time (sec) | 210 | 100 | 90 | 120 |
| | In plane thickness difference | 6 | 5 | 13 | 20 |
| | (μm) | | | | |
| | Circuit filling properties | OK | OK | NG | OK |
| | Dk | 4.0 | 4.0 | 4.6 | 4.6 |
| | Df | 0.010 | 0.010 | 0.020 | 0.020 |
| | Copper foil adhesion | 0.60 | 0.65 | 0.54 | 0.50 |
| | strength (kN/m) | | | | |

From the above results, it is found that the metal-clad laminate according to the embodiment has excellent in-plane thickness accuracy and excellent circuit filling properties.

First, from the comparison of Samples E1 to E4 in Table 1, it is found that as the polymer included in the resin composition is smaller in molecular weight, the resin flow is increased. When the resin flow is large, Va is reduced and thus Vb/Va is increased. On the other hand, comparing the result of Sample E5 with the result of Sample E1, when the amount of the blended polymer is increased, the resin flow is reduced and Va is increased. Therefore, Vb/Va is reduced. Within this range, there is no problem in circuit filling properties.

In Samples E1 to E5 in which PPE is used as a curing agent, the dielectric properties are excellent compared to Sample E6 in which a phenolic curing agent other than PPE is used. On the other hand, in Sample C2 in which Vb/Va is more than 15, the gel time is short and the circuit filling properties are deteriorated.

Form the results of Samples E7 to E9 shown in Table 2, it is found that when a large amount of inorganic filler is blended, the resin flow is reduced and the thickness accuracy is improved. However, the adhesion is slightly deteriorated.

On the other hand, in Samples C1 and C5 in which the resin flow is more than 5%, the in-plane thickness accuracy is low. Particularly, in Sample C5 in which the resin flow is as high as 20%, variation in in-plane thickness is significant.

As shown in Table 3, in Samples C3 and C4 in which only the amount of blended curing accelerator is reduced to increase the gel time, desired melt viscosity behavior and resin fluidity cannot be obtained and the circuit filling properties and thickness accuracy are deteriorated. On the other hand, in Sample E10 in which the amount of blended curing accelerator is slightly large compared to Sample E1, the resin flow is reduced and the gel time is shorter. Within this range, there is no problem in the circuit filling properties.

As described above, a metal-clad laminate and printed wiring board prepared using the prepreg according to the present disclosure have high thickness accuracy and excellent circuit filling properties. Therefore, the present disclosure is particularly suitably applicable to small thin electronic devices.

What is claimed is:

1. A prepreg comprising:
a fibrous substrate; and
a resin composition with which the substrate is impregnated, and which is heated and dried,
wherein a resin flow of the prepreg measured under conditions of 170° C. and 30 kgf/cm² according to IEC 60249-3-1, 1981, is 0% or more and 5% or less, and
in a dynamic viscoelasticity test under conditions of a temperature of 30° C. or higher and 200° C. or lower, a temperature rising rate of 3° C./min, and a frequency of 0.5 Hz, a relation of 1≦Vb/Va≦15 is established, where Va is a minimum melt viscosity of the resin composition collected from the prepreg, Vb is a melt viscosity of the collected resin composition at a temperature Tb, Tb=Ta+20° C., and Ta is a temperature when the melt viscosity is the minimum melt viscosity Va.

2. The prepreg according claim 1,
wherein a gel time, of the resin composition collected from the prepreg, measured according to IEC 60249-3-1, 1981, at 200° C. is 90 seconds or longer and 360 seconds or shorter.

3. The prepreg according claim 1,
wherein the resin composition includes
a polymer having a glass transition temperature of 100° C. or lower and a weight average molecular weight of 10,000 or more and 1,000,000 or less,
an epoxy resin curing agent having a phenolic hydroxyl group equivalent of 400 g/eq or more and 1,000 g/eq or less,
an epoxy resin having two or more epoxy groups in one molecule, and
an inorganic filler.

4. The prepreg according claim 3,
wherein the polymer has repeating units expressed by following structural formulae (I) and (II), and an epoxy group: 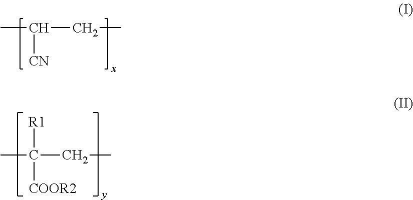
where a relation of 0≦x/(x+y)≦0.35 is established, R1 represents H or CH₃, and R2 represents H or an alkyl group, in the formulae (I) and (II).

5. The prepreg according claim 3,
wherein the epoxy resin curing agent is a polyphenylene ether copolymer having a number average molecular weight of 500 or more and 2,000 or less.

6. The prepreg according claim 3,
wherein the epoxy resin curing agent is a polyphenylene ether copolymer having an average number of phenolic hydroxyl groups of 1.5 or more and 3 or less at a molecule terminal in one molecule.

7. The prepreg according claim 3,
wherein the epoxy resin curing agent includes 2,6-dimethylphenol and at least one of a bifunctional phenol and a trifunctional phenol.

8. A metal-clad laminate comprising:
an insulting layer that is a cure product of the prepreg as defined in claim 1; and
a metal foil laminated on the insulating layer.

9. A printed wiring board comprising:
an insulting layer that is a cure product of the prepreg as defined in claim 1; and
a conductor pattern formed on the insulting layer.
